(19) United States
(12) Patent Application Publication
(10) Pub. No.: US 2006/0076694 A1
(43) Pub. Date: Apr. 13, 2006

(54) Semiconductor device package with concavity-containing encapsulation body to prevent device delamination and increase thermal-transferring efficiency

(75) Inventors: Hsien-Wei Chen, Tainan (TW); Hsueh-Chung Chen, Taipei (TW); Yi-Lung Cheng, Taipei (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD.

(21) Appl. No.: 10/962,478

(22) Filed: Oct. 13, 2004

(51) Int. Cl. H01L 23/28

(52) U.S. Cl. 257/787

(57) ABSTRACT

A semiconductor device package has a concavity-containing encapsulation body to prevent device delamination and increase thermal-transferring efficiency. An encapsulation body of polymer-based material encapsulates a semiconductor device and bonding wires, and a concavity structure is patterned on the encapsulation body by imprinting, laser drilling, photolithography, dry etching, die sawing, or other surface patterning technologies.

### BACKGROUND

The present invention relates to integrated circuit (IC) packages, and particularly to an IC package with a concavity-containing encapsulation body to prevent device delamination and increase thermal-transferring efficiency.

Semiconductor dies, also referred to as chips, undergo packaging or enclosure processes to prepare the dies for eventual use after wafer fabrication. Recently the semiconductor industry has introduced size-reduced packages, such as those with an area array format and a typical peripheral attachment of the input and output (I/O) terminals to a lead frame encapsulated in a plastic molded package. Well-known techniques used for bonding and electrically connecting a semiconductor die to a substrate, such as a printed circuit board (PCB), an interposer, or a carrier substrate, are flip-chip attachment, wire bonding, and tape automated bonding. For the wire bonding technology, the semiconductor die is directly attached to the substrate with an appropriate adhesive, such as an epoxy or adhesive tape. A plurality of bonding wires is then discretely attached to each bond pad on the semiconductor die and extends to a corresponding bonding pad on the substrate. The bonding wires are generally attached through one of three industry-standard wire bonding techniques including ultrasonic bonding, thermo-compression bonding and thermo-sonic bonding. A molding epoxy compound is typically used to encapsulate the bonding wires and prevent contamination from the plastic molded package. The plastic molded package also includes a metal lead frame bonded to the die. The lead frame forms terminal leads and provides internal signal, power and ground paths through the substrate to the die.

The plastic molded package provides effective enlargement of the distance or pitch between input/output contacts of the die and protects integrated circuits from mechanical and environmental damages, such as chemicals, moisture and gasses that could interfere with device performance. The epoxy encapsulation for the package presents several major advantages including light weight, low cost, and highly manufacturing efficiency, but sometimes causes device failure. For instance, internal delamination and component separation from the epoxy encapsulation frequently occur in the package subsequent to a molding procedure. The delamination refers to the disbanding effect at an interface of the epoxy encapsulation and the die, the lead frame, or the die attachment material. The delamination also means the loss of adhesion (chemical bonding) and differential contraction between the epoxy encapsulation and one or more of the other materials. If moisture enters along the delamination, the package base may swell making electrical interconnection to a printed circuit board (PCB) difficult or impossible.

The delamination at the interface of the die and the molded epoxy compound is primarily due to thermo-mechanical stresses generated by a CTE (coefficient of thermal expansion) mismatch effect there between. Such is the case with a wire-bonding package in which the semiconductor device, the molding epoxy compound, the lead frame and the adhesive tape have different CTEs, thus thermo-mechanical stresses are generated to cause insufficient bonding capability there between as the package is subjected to a temperature change from a relatively high molding temperature to room temperature. In addition, the conventional package is concerned with dissipation of heat generated by the die during operation. The molding epoxy compound, however, is poor in thermal conductivity, which limits the heat dissipation efficiency and thereby decreases, lifetime and quality of the plastic molded package.

Many approaches have been developed to address the problems caused by the CTE mismatch of materials in IC packaging, which are taught in U.S. Pat. No. 6,384,487, U.S. Pat. No. 6,700,210, and U.S. Pat. No. 6,580,170. Nevertheless, the conventional approaches are costly to fabricate and difficult to assemble, and problems of poor adhesion and low thermal-transferring efficiency usually accompany. Accordingly, an IC package with a reduced CTE mismatch between the die and the epoxy encapsulation for simplified assembly and improved reliability is called for.

### SUMMARY

It is an object of the present invention to provide a semiconductor device package with a concavity structure patterned on a top surface of an encapsulation body to prevent device delamination and increase thermal-transferring efficiency.

It is another object of the present invention to provide a semiconductor device package with a buffer layer interposed between a concavity-containing encapsulation body and a semiconductor device to further compensate the CTE mismatch effect there between.

It is another object of the present invention to provide a memory module having an IC package encapsulated by a concavity-containing encapsulation body.

It is another object of the present invention to provide an electronic system having a processor coupled to at least one memory module, in which the memory module has an IC package encapsulated by a concavity-containing encapsulation body.

To achieve the above objectives, the present invention provides an integrated circuit package. A substrate has a first contact area and a second contact area. A semiconductor device is attached to the first contact area of the substrate. A plurality of bonding wires is electrically connecting the semiconductor device to the second contact area of the substrate. An encapsulation body encapsulates the semiconductor device and the bonding wires, in which a concavity structure is formed on the encapsulation body. The encapsulation body is a polymer-based material, and the concavity structure comprises at least one of geometric-like concavities, at least one of mesh-like concavities, or combinations thereof. The concavity structure may be patterned on the top of said encapsulation body in a position corresponding to a projection area of said semiconductor device. The substrate may be electrically connected to an external board through a plurality of lead fingers or solder balls.

To achieve the above objectives, the present invention provides a fabrication method of an integrated circuit package. A substrate is provided with a first contact area and a second contact area. A semiconductor device is provided with an active surface and a non-active surface, in which the non-active surface is attached to the first contact area of the substrate. The active surface of the semiconductor device is connected to the second contact area of the substrate through bonding wires. An encapsulation body of polymer-based material is molded to encapsulate the semiconductor device and the bonding wires. A concavity structure is patterned on the encapsulation body by imprinting, laser drilling, photolithography, dry etching, die sawing or other surface patterning technologies. The concavity structure comprises at least one of geometric-like concavities, at least one of mesh-like concavities, or combinations thereof. The substrate may be electrically connected to an external board through a plurality of lead fingers or solder balls.

### BRIEF DESCRIPTION OF THE DRAWINGS

The aforementioned objects, features and advantages of this invention will become apparent by referring to the following detailed description of the preferred embodiment with reference to the accompanying drawings, wherein:

FIGS. 1A to 1D are solid diagrams illustrating semiconductor device packages according to embodiments of the present invention; and

FIG. 2A is a cross-sectional diagram along line 2-2 of FIG. 1A illustrating dimensions of a concavity structure of an encapsulation body; and

FIG. 2B is a cross-sectional diagram illustrating a concavity structure of an encapsulation body according to an embodiment of the present invention; and

FIGS. 3A and 3B are cross-section diagrams illustrating a buffer layer interposed between a semiconductor device and a concavity-containing encapsulation body according to embodiments of the present invention; and

FIGS. 3C and 3D are cross-section diagrams illustrating a buffer layer with additional elements interposed between the semiconductor device and the concavity-containing encapsulation body according to embodiments of the present invention; and

FIG. 4 is a cross-section diagram of a QFP-type package with a concavity-containing encapsulation body according to an embodiment of the present invention; and

FIG. 5 is a cross-section diagram of a BGA-type package with a concavity-containing encapsulation body according to an embodiment of the present invention.

### DESCRIPTION

The present invention provides a semiconductor device package with a concavity-containing encapsulation body to prevent delamination of the semiconductor device from the encapsulation body, which overcomes the aforementioned problems of the related art. The individual package of the present invention may be connected to, e.g., an interposer, a carrier substrate, a circuit board, a multi-chip module board, a memory module, or another semiconductor packages, with matching and complementary connective elements. The semiconductor device encapsulated in the individual package includes, for example integrated circuits (ICs), a memory device, a microprocessor, a logic array, a circuit module, and a subcomponent of a variety of electronic systems. One or more of the individual packages of the present invention may be incorporated in a semiconductor device assembly, a memory module, a computer system or other electronic systems.

Hereinafter, reference will now be made in detail to embodiments of the present invention, and examples of which are illustrated in the accompanying drawings. Wherever possible, the same reference numbers are used in the drawings and the description to refer to the same or like parts. In the drawings, the shape and thickness of an embodiment may be exaggerated for clarity and convenience. This description will be directed in particular to elements forming part of or cooperating more directly with apparatus in accordance with the present invention. It is to be understood that elements not specifically shown or described may take various forms well known to those skilled in the art. Further, when a layer is referred to as being on another layer or on a substrate, it may be directly on the other layer or on the substrate, or intervening layers may also be presented.

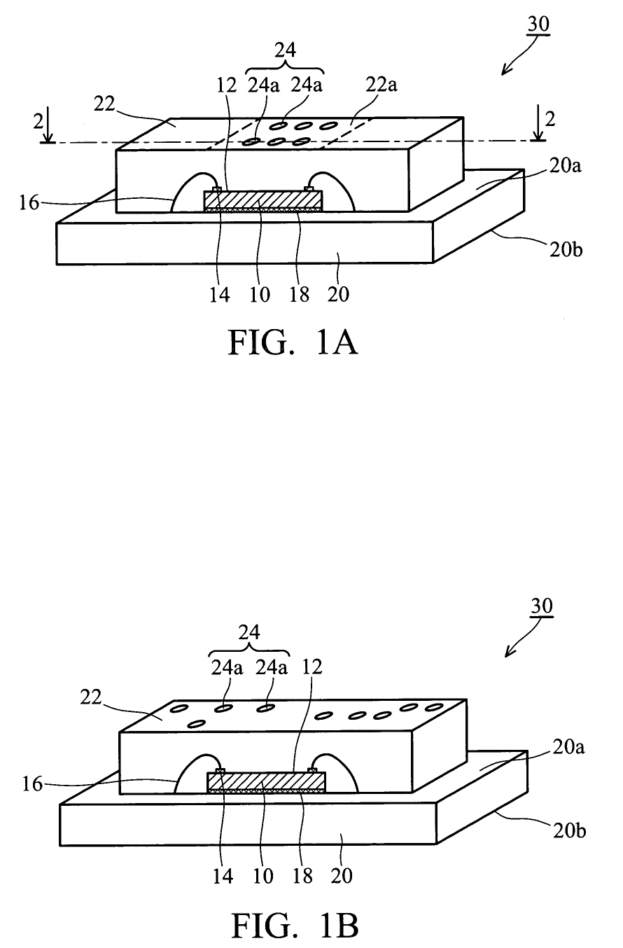

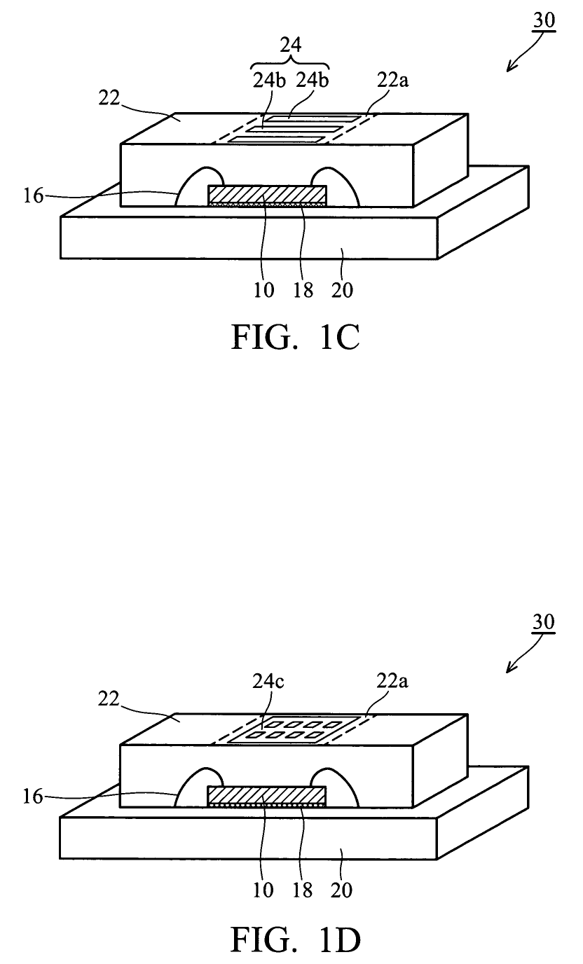

FIGS. 1A to 1D are solid diagrams illustrating semiconductor device packages according to embodiments of the present invention.

In FIG. 1A, a semiconductor device 10, also referred to as a semiconductor die or a semiconductor chip, is provided with an active surface 12 on which a plurality of bonding pads 14 are fabricated for external connections of the semiconductor device 10. The bonding pads 14 are electrically connected to a first surface 20a of a substrate 20 through bonding wires 16. Typically, the bonding pads 14 may extend to corresponding pads fabricated on a first contact area of the first surface 20a, or extend to lead fingers as the substrate 20 is integrated with a lead frame that provides internal signal, power and ground paths through the substrate 20 to the semiconductor device 10. In the drawings, the corresponding pads and the first contact area are omitted for clarity and convenience. The non-active surface of the semiconductor device 10, opposite to the active surface 12, is attached to the first surface 20a of the substrate 20 through an adhesive material 18, such as an epoxy or adhesive tape. Typically, the non-active surface of the semiconductor device 10 is attached to a second contact area of the first surface 20a, and reference numbers used for the non-active surface and the second contact area are omitted in the drawings for clarity. A second surface 20b of the substrate 20, opposite to the first surface 20a, may be connected to a printed circuit board (PCB), a multi-chip module board, a memory module, or another semiconductor packages with matching and complementary connective elements, such as a lead frame or solder balls. Moreover, a concavity-containing encapsulation body 22 encapsulates the semiconductor device 10 and the bonding wires 16 to form an individual package 30. The encapsulation body 22 may encapsulate parts or the whole of the substrate 20 dependent on package types and requirements.

The semiconductor device 10 may include integrated circuits capable of performing at least one of memory functions, logic functions, sensing functions, and processing functions. The semiconductor device 10 may include a memory device such as a DRAM (Dynamic Random Access Memory), a SRAM (Static Random Access Memory), Flash memories, or other embedded memory devices. The semiconductor device 10 may include an image sensor, a microprocessor or a logic array. The semiconductor device 10 may be a part of a circuit module that is at least one of memory modules, device drivers, power modules, communication modems and processor modules. The semiconductor device 10 may be a subcomponent of a variety of electronic systems, such as a control system, a printer, a scanner, a computer, a display system, a cell phone, an automated teller machine and others.

The bonding wires 16 are discretely attached to the bonding pads 14 on the semiconductor device 10 and extend to corresponding pads on the substrate 20 or lead fingers of a lead frame. The bonding wires 16 are generally attached through well-known wire bonding techniques including ultrasonic bonding, thermo-compression bonding, thermo-sonic bonding, and other emerging bonding technologies. The substrate 20 may include a carrier substrate, an interposer, support members, or conductive elements to mechanically support the semiconductor device 10 and provide contacts to external circuits. The material used to form the substrate 20 may include, for example glass, polyimide, metal, epoxy resin, and TAB tape dependent on package type and product requirements. As the substrate 20 is integrated with a lead frame, the interaction between the substrate and the lead frame may include through holes, thermo-compression bonding, welding, and adhesion films.

The encapsulation body 22 is a molding compound, and a concavity structure 24 is patterned on the surface of the encapsulation body 22. The molding compound may be a polymer-based material, and the term “polymer” includes thermosetting polymers, thermoplastic polymers, and mixtures thereof. The polymer-based material includes, for example plastic materials, epoxy resin, polyimide, PET (polyethylene terephthalate), PVC (polyvinyl chloride), PMMA (polymethylmethacrylate), and polymer components doped with specific fillers including fiber, clay, ceramic, and inorganic particles. In an embodiment, the molding compound is based on epoxy resin, such as epoxy cresol novolac (ECN), biphenyl epoxy resin, and multifunctional liquid epoxy resin. In an embodiment, the molding compound is epoxy resin optionally including one or more fillers to provide the composition with any of a variety of desirable properties. Examples of fillers are aluminum, titanium dioxide, carbon black, calcium carbonate, kaolin clay, mica, silica, talc, and wood flour. Methods of encapsulating the semiconductor device 10 and the bonding wires 16 with the polymer-based material include a glob top encapsulation and a transfer molding process. For example, in a molding system, the semiconductor device 10 attached to the substrate 20 is positioned within a molding chamber, and a molding compound is flown onto the semiconductor device 10, and then preheating and curing processes are performed to solidify the polymer-based material.

The present invention uses the polymer-based material for the encapsulation body 22 to provide mechanical protection of the semiconductor device 10 from external force and impact, and provide chemical protection of the semiconductor device 10 from environmental hazards such as chemicals, moisture and gasses. In order to release thermo-mechanical stresses and increase thermal transferring efficiency within the package 30, the present invention further provides the concavity structure 24 patterned on the surface of the encapsulation body 22 without sacrificing the above-described mechanical protection and chemical protection. The concavity structure 24 increases the surface area of the encapsulation body 22 can release the CTE mismatch effect between the molding compound and the semiconductor device 10, thus to prevent the device delamination and enhance adhesion property.

The concavity structure 24 also lengthens the path for dissipating the heat generated by the semiconductor device 10 as being in functioning, thus the thermal-transferring efficiency is increased. Compared with the conventional packages, the present invention integrates the concavity structure 24 into the encapsulation body 22 to solve the problem of IC delamination and achieve several advantages of light weight, low cost, and high manufacturing efficiency.

The concavity structure 24 is patterned on the surface of the molding compound without exposing the semiconductor device 10 and the bonding wires 16. In an embodiment, the concavity structure 24 may be randomly arranged or widely distributed over the surface of the molding compound, for example the peripheral portion, the central portion, or the combinations thereof. In an embodiment, the concavity structure 24 is patterned in a position corresponding to the semiconductor device 10, for example a projection area 22a of the semiconductor device 10, but this is a matter of design choice. The concavity structure 24 may be appropriately modified as a variety of geometric configurations dependent on product requirements and process limitations. Such a geometric configuration is relatively simple in design and practicable in mass production. Several exemplary designs of the concavity structure 24 are described as follows. In an embodiment, as shown in FIG. 1A, the concavity structure 24 comprises a plurality of circular-like concavities 24a that may be arranged randomly or in an array format within the projection area 22a. In an embodiment, as shown in FIG. 1B, the concavity structure 24 comprises a plurality of circular-like concavities 24a that are widely distributed over the surface of the molding compound. In an embodiment, as shown in FIG. 1C, the concavity structure 24 comprises a plurality of stripe-like trenches 24b that may be arranged in parallel, in perpendicular, in an uncrossed format, or in an intersected format. In an embodiment, as shown in FIG. 1D, the concavity structure 24 comprises at least one of mesh-like concavities 24c.

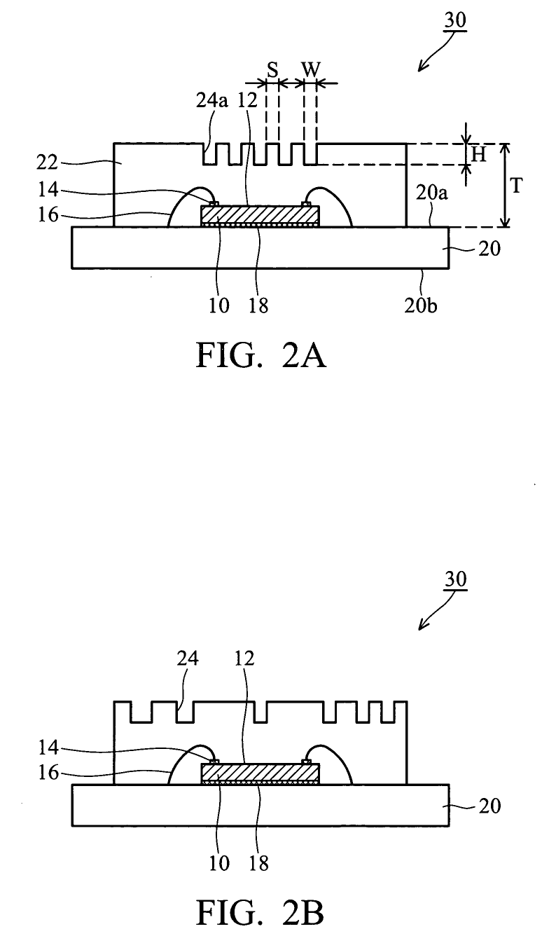

FIG. 2A is a cross-sectional diagram along line 2-2 of FIG. 1A, which illustrates dimensions of the circular-like concavity 24a, but the cross-sectional shape of the circular-like concavity 24a is a matter of choice. FIG. 2B is a cross-sectional diagram illustrating the circular-like concavities 24a that are widely distributed over the surface of the molding compound.

Depending on the device thickness and the package scale, the thickness T of the molding compound ranges about from 0.2 mm to 0.35 mm. Depending on product requirements and process limitations, the plurality of circular-like concavities 24a may have an identical dimension or different dimensions. For example, the depth H of each circular-like concavity 24a ranges about from about 1 μm to 200 μm, the diameter W of each circular-like concavity 24a satisfies the formula:

$$\frac{H}{W} ≅ 0.1 ∼ 50 ,$$

and the interval S between two adjacent circular-like concavities 24a satisfies the formula:

$$\frac{S}{W} \geq 0.5 .$$

The interval S between two adjacent circular-like concavities 24a may be larger than about 0.02μm. FIG. 2 may fit in with cross-section diagrams of the stripe-like trenches 24b and the mesh-like concavity 24c, and the depth, the width and the interval of the stripe-like trenches 24b and the mesh-like concavity 24c may conform to the ranges of H, W and S.

A variety of surface patterning technologies including, but not limited to, imprinting, laser drilling, photolithography, dry etching and die sawing may transfer patterns of the concavity structure 24 onto the surface of the molding compound that has been cured. In an embodiment of using the imprinting technology, a stamp having corresponding concave features is pressed into the molding compound, thereby creating a three-dimensional impression on the top of the encapsulation body 22. Such a stamp imprinting method is relatively simple in concave design and efficient in mass production. In an embodiment of using the photolithography technology that is relatively compatible in semiconductor manufacture processing, a solid photoresist layer is used as a mask for exposure, and then a developing process or a plasma etching process may be employed to remove exposed areas of the molding compound until the predetermined depth H is reached. Alternatively, the concavity structure 24 may be in-situ patterned during the formation of the molding compound.

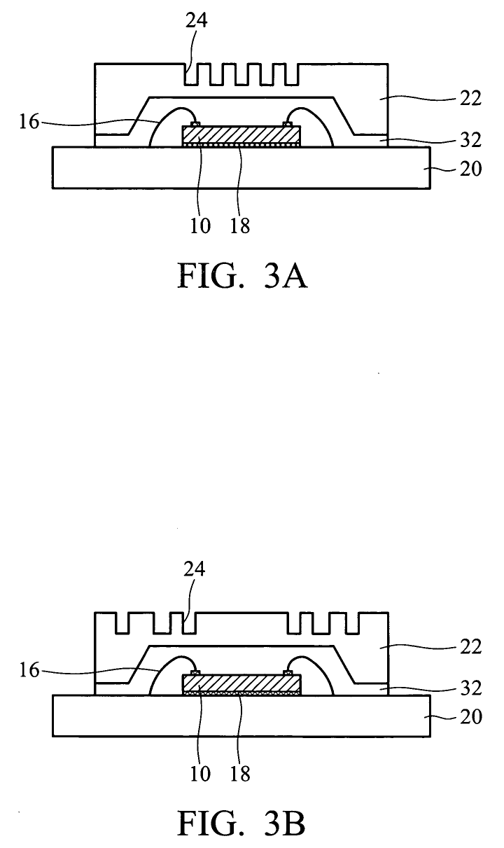

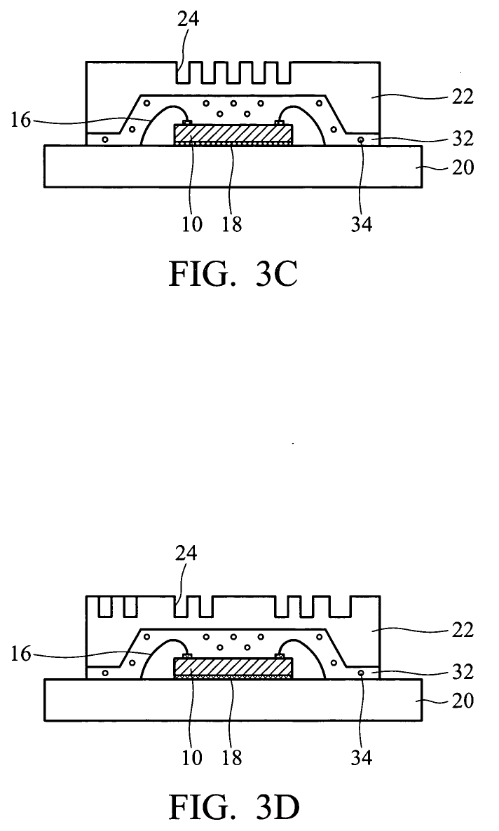

In addition to the concave designs, the present invention provides a buffer layer interposed between the semiconductor device 10 and the concavity-containing encapsulation body 22 to further compensate and reduce the mismatch CTE effect generated there between, resulting in a great improvement in package reliability and device performance. FIGS. 3A and 3B are cross-section diagrams illustrating a buffer layer 32 interposed between the semiconductor device 10 and the concavity-containing encapsulation body 22. The buffer layer 32 is deposited to cover the semiconductor device 10 and the bonding wires 16, and then encapsulated by the concavity-containing encapsulation body 22. The buffer layer 32 may be a dielectric layer, such as an oxide-containing material or a nitride-containing material.

FIGS. 3C and 3D are cross-section diagrams illustrating a buffer layer 32 with additional elements 34 interposed between the semiconductor device 10 and the concavity-containing encapsulation body 22. The additional elements 34 may be an additive, such as fiber, clay, inorganic particles incorporated with the buffer layer 32. The additional elements 34 may be ions, such as carbon ions and nitrogen ions implanted into the buffer layer 32. The additional elements 34 may be bubbles or voids formed in the buffer layer 32.

The semiconductor device package of the present invention may be used in wire-bonding package applications incorporated with various polymer-molded packages including, but not limited to, Quad Flat Package (QFP) type, Quad Flat Non-leaded (QFN) type, and Ball Grid Array (BGA) type. A variety of exemplary packages are described now.

The QFP type is formed with a semiconductor die connected to a lead frame and being encapsulated to form a package such that a plurality of lead fingers extends laterally outwardly from each side of the periphery of a polymer encapsulation body. According to the substrate material and the interaction between the substrate and the lead frame, the QFP packages are termed “PACKTHOL”, “PC-QFP”, “Hyper Quad”, “TAB-QFP”, “BOL PKG” and “COF”. According to the shape of the outer lead, there are three types of Quad Flat Package (QFP), known as Quad Flat I-leaded (QFI) type, Quad Flat J-leaded (QFJ) type, and Quad Flat Non-leaded (QFN) type. The QFN type uses the bottom surface of the lead frame for electrically bonding to a printed circuit board rather than using external pins. This benefit allows the QFN type to be made smaller in size, and the non-leaded design alllows the QFN type to accord with the demand of being light, thin and compact for modern electricity components, especially components used in mobile electronics, such as cellular phone or notebook computer, etc.

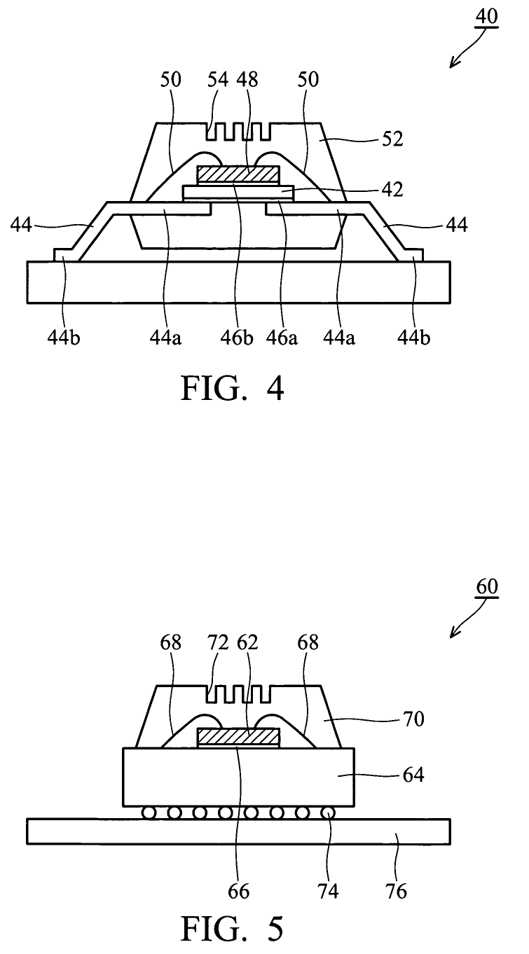

FIG. 4 is a cross-section diagram of a QFP-type package with a concavity-containing encapsulation body according to an embodiment of the present invention. The exemplary package 40 is termed COF (chip on film), which employs a substrate 42 of a polyimide film to be bonded onto inner parts 44a of lead fingers 44 through a first adhesion material 46a on the lower side of the substrate 42. A semiconductor device 48 is mounted onto the front side of the substrate 42 through a second adhesion material 46b. The active surface of the semiconductor device 48 is electrically connected to the inner parts 44a of the lead fingers 44 by bonding wires 50. The substrate 42, the semiconductor device 48, the bonding wires 50 and the inner parts 44a of the lead fingers 44 are encapsulated by a polymer-based encapsulation body 52. A concavity structure 54 is patterned on the top of the polymer-based encapsulation body 52 by imprinting, photolithography, dry etching, or other surface patterning technologies. In addition, the outer parts 44b of the lead fingers 44 may be optionally connected to an external board 56, such as a printed circuit board, a module board, or another semiconductor packages. The concavity structure 54 prevents the device delamination caused by the CTE mismatch effect, and provides an extra path for heat dissipating.

The BGA type uses a substrate as a chip carrier whose front surface is used for wire bonding one or more semiconductor dies and whose back surface is provided with a plurality of array-arranged solder balls, thus increasing the number of I/O connections. During a SMT (surface mount technology) process, the BGA package is mechanically bonded and electrically coupled to an external board by means of these solder balls. FIG. 5 is a cross-section diagram of a BGA-type package with a concavity-containing encapsulation body according to an embodiment of the present invention. In an exemplary BGA package 60, a semiconductor device 62 is adhesively attached to a substrate 64 by an adhesive material 66, and an active surface of the semiconductor device 62 is connected to the substrate 64 by bonding wires 68. By a transfer molding process and an oven curing procedure, an encapsulation body 70 of molding compound is provide to encapsulate the semiconductor device 62 and the bonding wires 68. A concavity structure 72 is patterned on the top of the encapsulation body 72 by imprinting, photolithography, dry etching, or other surface patterning technologies. A plurality of conductive balls 74 arranged in an array format is attached to the backside of the substrate 64 through a solder reflow process, which permits the package to be mounted onto an external board 76 including a printed circuit board, a module board, or another semiconductor packages. The concavity structure 72 prevents the device delamination caused by the CTE mismatch effect, and provides an extra path for heat dissipating.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

1. An integrated circuit package, comprising:
a substrate having a first contact area and a second contact area;
a semiconductor device attached to said first contact area of said substrate;
a plurality of bonding wires electrically connecting said semiconductor device to said second contact area of said substrate; and
an encapsulation body encapsulating said semiconductor device and said bonding wires, in which a concavity structure is formed overlying said encapsulation body and located on a surface of the integrated circuit package.

2. The integrated circuit package of claim 1, wherein said encapsulation body is a polymer-based material.

3. The integrated circuit package of claim 1, wherein said concavity structure comprises at least one of geometric-like concavities, at least one of mesh-like concavities, or combinations thereof.

4. The integrated circuit package of claim 1, wherein said concavity structure is formed on the top of said encapsulation body in a position corresponding to a projection area of said semiconductor device.

5. The integrated circuit package of claim 1, wherein said substrate comprises a third contact area electrically connected to an external board through a plurality of lead fingers or solder balls.

6. The integrated circuit package of claim 1, further comprising a buffer layer interposed between said encapsulation body and said semiconductor device.

7. The integrated circuit package of claim 1, wherein said encapsulation body encapsulates a portion of said substrate.

8. A method of forming an integrated circuit package, comprising the steps of:
providing a substrate comprising a first contact area and a second contact area;
providing a semiconductor device with an active surface and a non-active surface;
attaching said non-active surface of said semiconductor device to said first contact area of said substrate;
wire bonding said active surface of said semiconductor device to said second contact area of said substrate; and
forming an encapsulation body with a concavity structure to encapsulate said semiconductor device and said bonding wires.

9. The method of forming an integrated circuit package of claim 8, wherein said encapsulation body is a polymer-based material.

10. The method of forming an integrated circuit package of claim 8, wherein said concavity structure comprises at least one of geometric-like concavities, at least one of mesh-like concavities, or combinations thereof.

11. The method of forming an integrated circuit package of claim 8, wherein said concavity structure is patterned overlying said encapsulation body by imprinting, laser drilling, photolithography, dry etching, die sawing, or combinations thereof.

12. The method of forming an integrated circuit package of claim 8, further comprising the step of electrically connecting said substrate to an external board through a plurality of lead fingers or solder balls.

13. The method of forming an integrated circuit package of claim 8, before the formation of the encapsulation body, further comprising the step of depositing a buffer layer overlying said semiconductor device.

14. A memory module, comprising:
a substrate comprising a first contact area, a second contact area and a third area;
a semiconductor device comprising an active surface and a non-active surface, wherein said non-active surface of said semiconductor device is attached to said first contact area of said substrate;
a plurality of bonding wires electrically connecting said active surface of said semiconductor device to said second contact area of said substrate;
an encapsulation body encapsulating said semiconductor device and said bonding wires, wherein a concavity structure is formed overlying said encapsulation body; and
a module board electrically connected to said third contact area of said substrate.

15. The memory module of claim 14, wherein said encapsulation body is a polymer-based material.

16. The memory module of claim 14, wherein said concavity structure comprises at least one of geometric-like concavities, at least one of mesh-like concavities, or combinations thereof.

17. The memory module of claim 14, wherein said concavity structure is patterned on the top of said encapsulation body in a position corresponding to a projection area of said active surface of said semiconductor device.

18. The memory module of claim 14, wherein said third contact area of said substrate is electrically connected to said module board through a plurality of lead fingers or solder balls.

19. A semiconductor device assembly, comprising:
a plurality of lead fingers comprising a first part and a second part;
a substrate comprising a first side and a second side, wherein said first side of said substrate is attached to said first part of said lead fingers;
a semiconductor device comprising an active surface and a non-active surface, wherein said non-active surface is attached to said second side of said substrate.
a plurality of bonding wires electrically connecting said active surface of said semiconductor device to said first part of said lead fingers;
an encapsulation layer encapsulating said active surface of said semiconductor device, said bonding wires, said substrate, and said first part of said lead fingers, wherein a concavity structure is formed overlying said encapsulation body; and
a circuit board electrically connected to said second part of said lead fingers.

20. The semiconductor device assembly of claim 19, wherein said encapsulation body is a polymer-based material.

21. The semiconductor device assembly of claim 19, wherein said concavity structure comprises at least one of geometric-like concavities, at least one of mesh-like concavities, or combinations thereof.

22. The semiconductor device assembly of claim 19, wherein said concavity structure is formed on said encapsulation body in a position corresponding to a projection area of said active surface of said semiconductor device.

23. A semiconductor device assembly, comprising:
a substrate comprising a first side and a second side, and said first side comprises a first contact area and a second contact area;
a semiconductor device comprising an active surface and a non-active surface, wherein said non-active surface is attached to said first contact area of said first side of said substrate;
a plurality of bonding wires electrically connecting said active surface of said semiconductor device to said second contact area of said first side of said substrate;
an encapsulation layer encapsulating said active surface of said semiconductor device, said bonding wires, and said first side of said substrate, wherein a concavity structure is formed overlying said encapsulation body;
a plurality of solder balls formed on said second side of said substrate; and
a circuit board electrically connected to said second side of said substrate through said solder balls.

24. The semiconductor device assembly of claim 23, wherein said encapsulation body is a polymer-based material.

25. The semiconductor device assembly of claim 23, wherein said concavity structure comprises at least one of geometric-like concavities, at least one of mesh-like concavities, or combinations thereof.

26. The semiconductor device assembly of claim 23, wherein said concavity structure is formed on said encapsulation body in a position corresponding to a projection area of said active surface of said semiconductor device.
